(19) United States
(12) Patent Application Publication
(10) Pub. No.: US 2025/0236511 A1
(43) Pub. Date: Jul. 24, 2025

(54) Inertial Sensor And Electronic Component

(71) Applicant: SEIKO EPSON CORPORATION, Tokyo (JP)

(72) Inventor: Tomonaga KOBAYASHI, Chino (JP)

(21) Appl. No.: 19/032,578

(22) Filed: Jan. 21, 2025

(30) Foreign Application Priority Data
Jan. 22, 2024 (JP) 2024-007235

(51) Int. Cl. B81C 1/00; B81B 7/00

(52) U.S. Cl. CPC B81C 1/00269; B81B 7/007; B81B 2201/0235; B81B 2201/0242; B81B 2207/07; B81C 2203/0109; B81C 2203/037

(57) ABSTRACT

An inertial sensor or an electronic component includes a base body, a lid body, a functional element disposed between the base body and the lid body, a metal eutectic layer configured to bond the base body and the lid body to each other in a bonding region located on a periphery of the functional element, a plurality of interconnections which passes through the bonding region to be coupled to the functional element, and a dummy pattern disposed in the bonding region so as to overlap the metal eutectic layer at a same height as the interconnections.

The present application is based on, and claims priority from JP Application Serial Number 2024-007235, filed Jan. 22, 2024, the disclosure of which is hereby incorporated by reference herein in its entirety.

### BACKGROUND

### 1. Technical Field

The present disclosure relates to an inertial sensor and an electronic component.

### 2. Related Art

In the past, there has been known a sensor device including a base body having a cavity, a sensor element suspended in the cavity, and a lid body sealing the cavity. The base body and the lid body were bonded via a bonding material. The bonding material was required to have a high bonding strength and a high long-term reliability of sealing.

For example, US 2010/0059835 discloses use of an AlGe eutectic as the bonding material. According to this document, the concentration of Ge in the AlGe eutectic is uniform or a function of a distance from the lid body or the base body.

US 2010/0059835 is an example of the related art.

However, in the technology disclosed in US 2010/0059835, there is a concern that the bonding strength with the bonding material may decrease. Particularly, when the concentration of Ge decreases in accordance with the distance from the lid body, the AlGe eutectic layer cannot be realized at the base body side, and only the Al layer is formed, which may cause a deterioration of the bonding strength. Further, in the case of the eutectic bonding, there is a possibility that it is difficult to provide the eutectic bonding part immediately above interconnections due to the unevenness caused by an extraction interconnection from a sensor element, or a bonding material protrudes from a bonding region to affect the sensor element. That is, an inertial sensor and an electronic component which are high in bonding strength between the base body and the lid body and are excellent in reliability have been required.

### SUMMARY

An inertial sensor according to an aspect of the present application is an inertial sensor of a capacitance change type including a base body, a lid body, a functional element disposed between the base body and the lid body, a metal eutectic layer configured to bond the base body and the lid body to each other in a bonding region located on a periphery of the functional element, a plurality of interconnections which passes through the bonding region to be coupled to the functional element, and a dummy pattern disposed in the bonding region so as to overlap the metal eutectic layer at a same height as the interconnections.

An electronic component according to an aspect of the present application includes a base body, a lid body, a functional element disposed between the base body and the lid body, a metal eutectic layer configured to bond the base body and the lid body to each other in a bonding region located on a periphery of the functional element, a plurality of interconnections which passes through the bonding region to be coupled to the functional element, and a dummy pattern disposed in the bonding region so as to overlap the metal eutectic layer at a same height as the interconnections.

### BRIEF DESCRIPTION OF THE DRAWINGS

FIG. 1 is a plan view of an inertial sensor according to Embodiment 1.

FIG. 2 is a cross-sectional view of the inertial sensor along a center line of FIG. 1.

FIG. 3 is a cross-sectional view of an essential part of a base body and a lid body to be bonded to each other.

FIG. 4 is an enlarged view of the part b of FIG. 2.

FIG. 5 is a cross-sectional view along the line c-c in FIG. 1.

FIG. 6 is a cross-sectional view along the line d-d in FIG. 1.

FIG. 7 is a cross-sectional view showing the cross-sectional view shown in FIG. 4 in terms of a layer configuration.

FIG. 8 is a plan view of an inertial sensor according to Embodiment 2.

FIG. 9 is a partially enlarged view in the plan view of FIG. 8.

FIG. 10 is a cross-sectional view of an essential part of a lid body according to Embodiment 3.

FIG. 11 is an exploded perspective view of an inertial measurement device.

FIG. 12 is a perspective view of a board.

### DESCRIPTION OF EMBODIMENTS

### Embodiment 1

### Configuration of Inertial Sensor

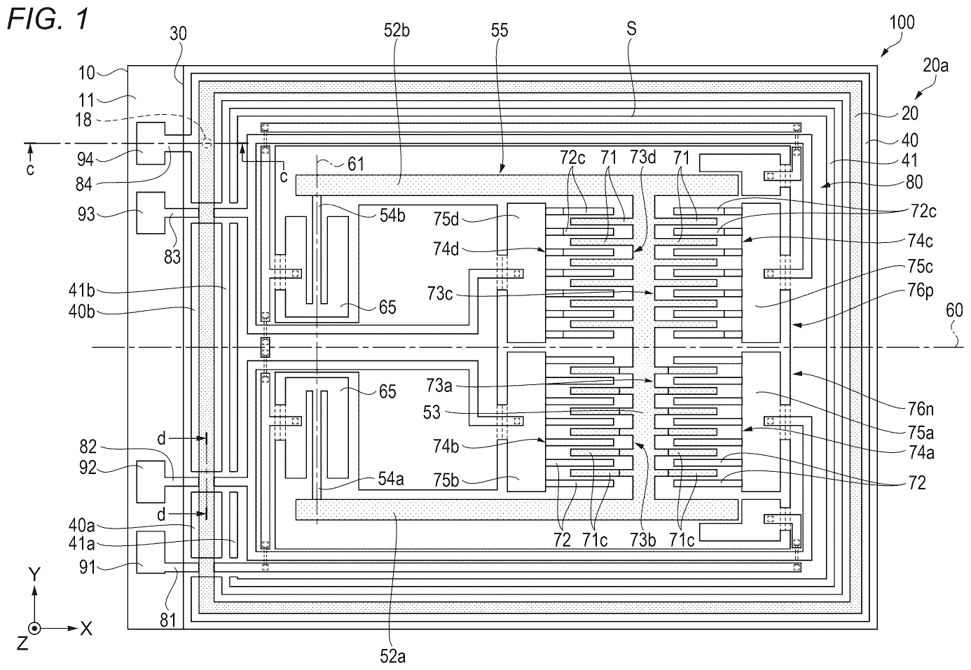

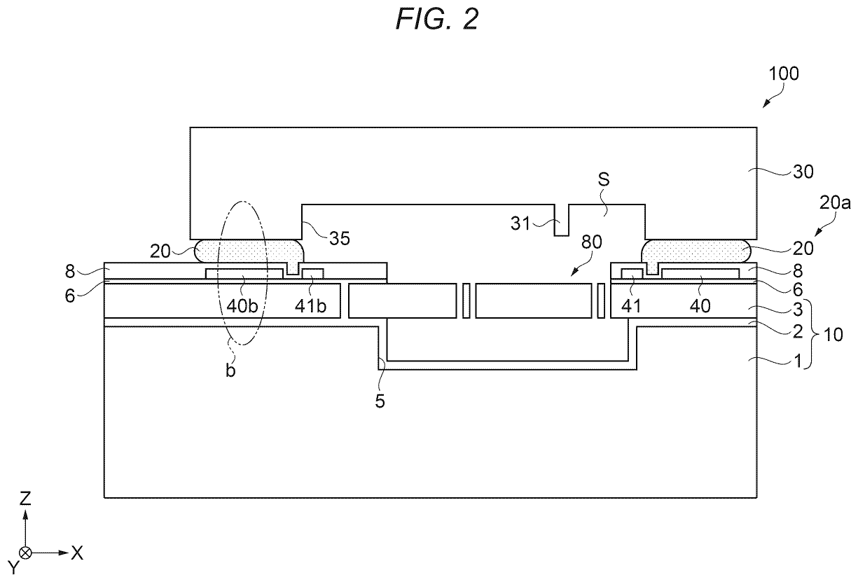

FIG. 1 is a plan view of an inertial sensor according to Embodiment 1. FIG. 2 is a cross-sectional view of the inertial sensor along a center line 60 of FIG. 1.

A configuration of an inertial sensor 100 according to the present embodiment will be described with reference to FIG. 1 and FIG. 2.

The inertial sensor 100 is, for example, an acceleration sensor that detects acceleration in a vertical direction. Note that an X axis, a Y axis, and a Z axis which are three axes perpendicular to each other are shown in the drawings. In the present embodiment, a Z-axis direction is defined as the vertical direction, but this is not a limitation. A direction along the X axis is referred to as an “X direction”, a direction along the Y axis is referred to as a “Y direction”, and a direction along the Z axis is referred to as a “Z direction”. Further, a tip side of an arrow in each axis direction is also referred to as “positive side”, and a base side of the arrow is also referred to as “negative side”. For example, the Y direction refers to both a direction toward the positive side in the Y direction and a direction toward the negative side in the Y direction. Further, the positive side in the Z direction is also referred to as “upper side”, and the negative side in the Z direction is also referred to as “lower side”. Further, in each of the drawings described below, in order to make the description easy to understand, dimensions and scales different from actual ones may be used in some cases.

The inertial sensor 100 is a uniaxial acceleration sensor formed of a MEMS (Micro Electro Mechanical Systems) device. Note that the inertial sensor 100 is not limited to the acceleration sensor, but is sufficiently an inertial sensor of a variable capacitance type, and may be, for example, an angular velocity sensor.

As shown in FIG. 2, the inertial sensor 100 includes a base body 10, a sensor element 80 disposed above the base body 10, a lid body 30 that covers the sensor element 80, and so on.

The base body 10 is an SOI (Silicon On Insulator) substrate, and is configured by stacking a substrate 1, an insulating layer 2, and a semiconductor layer 3 in this order along the Z direction. The substrate 1 is a single-crystal silicon substrate, and the insulating layer 2 is disposed on an upper surface of the substrate 1. The insulating layer 2 is an embedded insulating layer made of SiO₂.

The substrate 1 is provided with a recessed part 5 which is dug from a peripheral edge portion thereof. The recessed part 5 is a cavity, and is a region forming a housing space S for housing the sensor element 80. Due to the recessed part 5, there is provided a configuration in which a movable body 55 (FIG. 1) of the sensor element 80 is swingable. Note that the insulating layer 2 is disposed on a bottom surface of the recessed part 5 in FIG. 2, but can be eliminated.

The semiconductor layer 3 is a conductive silicon substrate doped with impurities such as phosphorus (P), boron (B), or arsenic (As). In a preferred example, the semiconductor layer 3 and the insulating layer 2 are bonded with Si—SiO₂ fusion bond.

The sensor element 80 is a functional element and is formed by etching and patterning the semiconductor layer 3. In a preferred example, a deep etching technique using a Bosch process is used. The sensor element 80 is fixed to the substrate 1 with fixing parts 65 (FIG. 1).

As a preferred example, a silicon substrate is used as the lid body 30. The lid body 30 is provided with a recessed part 35 which is dug from a peripheral edge portion thereof. The recessed part 35 is a region forming the housing space S for housing the sensor element 80. The recessed part 35 is provided with a stopper part 31 that is a protrusion for restricting an excessive oscillation of the movable body 55 of the sensor element 80.

As shown in FIG. 2, the base body 10 and the lid body 30 are bonded to each other with the metal eutectic layer 20 in a circumferential edge portion thereof. Details of the metal eutectic layer 20 will be described later. In a preferred example, the housing space S is filled with an inert gas such as nitrogen, helium, or argon, and hermetically sealed. It is preferable that the housing space S has a substantially atmospheric pressure at a use temperature environment of about −40° C. to 120° C.

### Configuration of Sensor Element

As shown in FIG. 1, the sensor element 80 as a functional element is an acceleration sensor that detects the acceleration in the Z direction, and adopts a so-called unilateral seesaw structure in which the movable body 55 swings centering on an oscillation axis 61.

The sensor element 80 includes the fixing parts 65, the movable body 55 which is swingable about the oscillation axis 61 passing through the center of the fixing part 65 and parallel to the Y axis, a first torsion spring 54a and a second torsion spring 54b which couple the fixing parts 65 and the movable body 55, and so on. The fixing parts 65 are fixed to a pedestal portion (not shown) protruding from the substrate 1 (FIG. 2). The periphery of the pedestal portion forms the recessed part 5 (FIG. 2) to form the configuration in which the movable body 55 is swingable. Note that in FIG. 1, a line segment which is perpendicular to the oscillation axis 61 and passes through the center of the sensor element 80 along the X axis is defined as a center line 60.

The movable body 55 includes a first bar 52a extending from the first torsion spring 54a toward the positive X direction, a second bar 52b extending from the second torsion spring 54b toward the positive X direction, and a third bar 53 coupling the first bar 52a and the second bar 52b to each other.

The third bar 53 is provided with four movable electrode groups 73a to 73d each having a comb-like shape.

The movable electrode group 73a is formed of six movable electrodes 71c extending toward the positive X direction from the third bar 53 at the negative Y side of the center line 60.

The movable electrode group 73b is formed of six movable electrodes 71c extending toward the negative X direction from the third bar 53 at the negative Y side of the center line 60. Note that the number of movable electrodes 71c is not limited to six, and is sufficiently two or more.

The movable electrode groups 73c and 73d are disposed at the positive Y positions line symmetrical about the center line 60 as an axis of symmetry with respect to the movable electrode groups 73a and 73b, respectively.

Further, at the substrate 1 (FIG. 2) side, fixed electrode groups 74a to 74d respectively opposed to the movable electrode groups 73a to 73d are provided.

The fixed electrode group 74a includes a support part 75a fixed to the substrate 1 and seven fixed electrodes 72 extending toward the negative X direction from the support part 75a.

The fixed electrode group 74b includes a support part 75b fixed to the substrate 1 and seven fixed electrodes 72 extending toward the positive X direction from the support part 75b. Note that the number of fixed electrodes is not limited to seven, and is sufficiently a number corresponding to the number of movable electrodes 71c.

The fixed electrode groups 74c and 74d are disposed at the positive Y side at positions line symmetrical about the center line 60 as an axis of symmetry with respect to the fixed electrode groups 74a and 74b, respectively.

A detector configured with the fixed electrode group 74a and the movable electrode group 73a and a detector configured with the fixed electrode group 74b and the movable electrode group 73b are collectively referred to as an N-type detector 76n.

In the N-type detector 76n, a parallel plate type capacitance is formed by the fixed electrode 72 and the movable electrode 71c disposed so as to be opposed to each other. The capacitance changes in accordance with a change in an overlapping area between the fixed electrode 72 and the movable electrode 71c due to a displacement of the movable electrode 71c by the acceleration.

Similarly, a detector configured with the fixed electrode group 74c and the movable electrode group 73c and a detector configured with the fixed electrode group 74d and the movable electrode group 73d are collectively referred to as a P-type detector 76p. In the P-type detector 76p, a parallel plate type capacitance is formed by the fixed electrode 72c and the movable electrode 71 disposed so as to be opposed to each other. The capacitance changes in accordance with a change in an overlapping area between the fixed electrode 72c and the movable electrode 71 due to a displacement of the movable electrode 71 by the acceleration.

The movable electrodes 71c of the N-type detector 76n are thinner in thickness in the Z direction than the movable electrodes 71 of the P-type detector 76p. Particularly, the movable electrodes 71c are each thinned by being cut in a stepwise manner in the middle in the extending direction from the same thickness as that of the third bar 53 at the base. Accordingly, the thicknesses of all the twelve movable electrodes 71c at the positive Z side are thinned in portions opposed to the fixed electrodes 72.

The fixed electrodes 72c of the P-type detector 76p are thinner in thickness in the Z direction than the fixed electrodes 72 of the N-type detector 76n. Particularly, the fixed electrodes 72c are each thinned by being cut in a stepwise manner in the middle in the extending direction from the thickness in the base at the support parts 75c, 75d side. Accordingly, the thicknesses of all the fourteen fixed electrodes 72c at the positive Z side are thinned in portions opposed to the movable electrodes 71.

Due to such a configuration, when the acceleration is generated in the positive Z direction, the overlapping area decreases in the N-type detector 76n, and the overlapping area is maintained in the P-type detector 76p. Further, when the acceleration in the negative Z direction is generated, the overlapping area is maintained in the N-type detector 76n, and the overlapping area decreases in the P-type detector 76p.

Based on such a correlation, in the sensor element 80, it is possible to detect the acceleration in the positive Z direction and the acceleration in the negative Z direction by performing the differential detection of a change in the overlapping area in the N-type detector 76n and the P-type detector 76p as a change in electrostatic capacitance.

### Configuration of Bonding Region

As shown in FIG. 1, the base body 10 has a substantially rectangular shape, and the short side at the negative side in the X direction forms a protruding portion 11 protruding from a short side of the lid body 30. Terminals 91 to 94 for external coupling are provided to the protruding portion 11.

The terminal 91 is a movable electrode terminal and is electrically coupled to all the movable electrodes 71, 71c with an interconnection 81.

The terminal 92 is an N-type fixed electrode terminal, and is electrically coupled to all the fixed electrodes 72 of the N-type detector 76n with an interconnection 82.

The terminal 93 is a P-type fixed electrode terminal, and is electrically coupled to all the fixed electrodes 72c of the P-type detector 76p with an interconnection 83.

The terminal 94 is a GND terminal and is electrically coupled to the metal eutectic layer 20 with an interconnection 84. Note that the coupling configuration between the terminal 94 and the metal eutectic layer 20 will be described later in detail.

The base body 10 and the lid body 30 are bonded in a bonding region 20a having a quadrangular annular shape surrounding the sensor element 80. The bonding region 20a is a quadrangular annular area slightly smaller than the outer circumferential edge of the lid body 30. The metal eutectic layer 20 is formed in the bonding region 20a. Further, the metal eutectic layer 20 is formed so as to cross the interconnections 81 to 83 in a plan view.

In other words, the inertial sensor 100 of the capacitance change type includes the base body 10, the lid body 30, the sensor element 80 as a functional element disposed between the base body 10 and the lid body 30, and the metal eutectic layer 20 for bonding the base body 10 and the lid body 30 to each other on the periphery of the sensor element 80.

A first dummy pattern 40 is disposed at the lower side of the metal eutectic layer 20. The first dummy pattern 40 is an interconnection layer formed in the same process as that of the interconnections 81 to 84, and is disposed in a quadrangular annular shape along the bonding region 20a.

In the first dummy pattern 40, a portion which is located in the bonding region 20a, and through which the interconnections 81 to 83 pass is decoupled, and the first dummy pattern 40 and the interconnections are electrically insulated from each other. The first dummy pattern 40 is formed as an island pattern in the portion decoupled by the interconnections. An island-shaped first dummy pattern 40a is disposed between, for example, the interconnection 81 and the interconnection 82. Similarly, an island-shaped first dummy pattern 40b is disposed between the interconnection 82 and the interconnection 83. In other words, the first dummy pattern 40 is insulated from the plurality of interconnections 81 to 83, and the first dummy pattern 40 is disposed between the plurality of interconnections 81 to 83 in a plan view. Further, the plurality of interconnections 81 to 83 passes through the bonding region 20a and is coupled to the sensor element 80. Note that when n the island-shaped patterns are not distinguished, the first dummy patterns 40a, 40b are inclusively referred to as the first dummy pattern 40.

Further, a second dummy pattern 41 having a quadrangular annular shape slightly smaller than the first dummy pattern 40 is disposed at the inner circumferential side of the first dummy pattern 40. Similarly to the first dummy pattern 40, the second dummy pattern 41 is an interconnection layer formed in the same process as that of the interconnections 81 to 84, a portion of the second dummy pattern 41 through which the interconnections 81 to 83 pass is decoupled, and thus, the second dummy pattern 41 is electrically insulated from the interconnections. An island-shaped second dummy pattern 41a is disposed between the interconnection 81 and the interconnection 82, and an island-shaped second dummy pattern 41b is disposed between the interconnection 82 and the interconnection 83. When the island-shaped patterns are not distinguished, the second dummy patterns 41a, 41b are inclusively referred to as the second dummy pattern 41. Note that a dummy pattern having a similar quadrangular annular shape may be disposed at the outer circumferential side of the first dummy pattern 40. In other words, an n-th dummy pattern different from the first dummy pattern 40 may be further disposed at either one or both of the inner circumferential side and the outer circumferential side of the first dummy pattern 40.

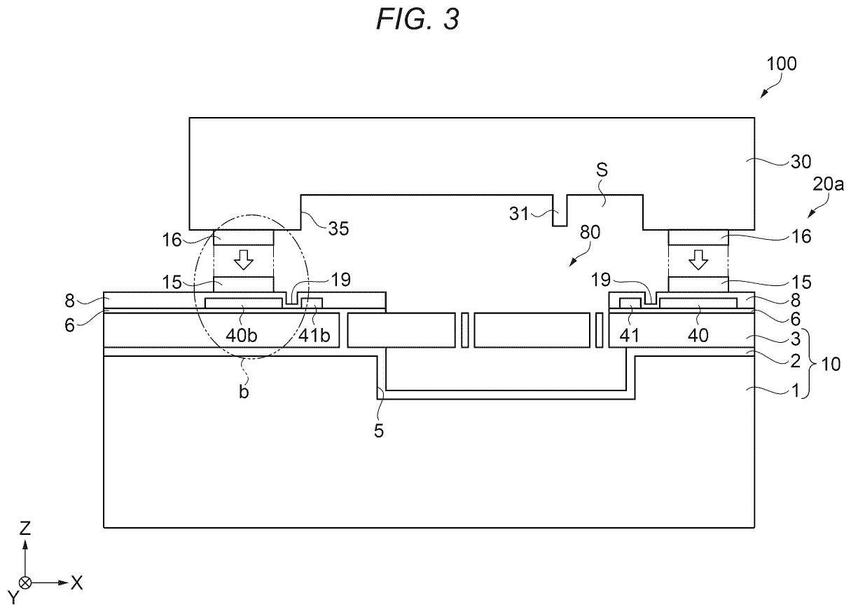

FIG. 3 is a cross-sectional view of an essential part of the base body and the lid body to be bonded to each other, and corresponds to FIG. 2.

As shown in FIG. 3, before the formation of the metal eutectic layer 20, the base body 10 is provided with the first bonding part 15, and the lid body 30 is provided with a second bonding part 16.

The first bonding part 15 is an AlCu layer as a first metal layer. The first bonding part 15 is deposited using, for example, a DC sputtering method, and is then patterned. Note that the first bonding part 15 is also referred to as a first metal layer 15. Cu in the AlCu layer is mixed for the purpose of preventing electromigration, and the content thereof is low. Accordingly, the main component of the first bonding part 15 is Al.

The second bonding part 16 is a Ge layer as a second metal. In the present embodiment, the second bonding part 16 made of Ge is deposited directly on the silicon substrate constituting the lid body 30. In a preferred example, a Ge layer is formed using a DC sputtering method, and then patterning the Ge layer to form the second bonding part 16. The second bonding part 16 is also referred to as a second metal layer 16. In other words, the main component of the first metal layer is Al, and the main component of the second metal layer is Ge.

The first bonding part 15 and the second bonding part 16 are bonded to each other in a heating step and a weighting step. Particularly, a stacked body in which the base body 10 and the lid body 30 are stacked on one another is heated to a temperature equal to or higher than an eutectic temperature of the first metal layer 15 and the second metal layer 16, and further, a weight is applied thereto in the heated state to thereby achieve the eutectic bonding. Note that the eutectic temperature of AlGe is about 420° C. In a preferred example, the stacked body is set on a stage of a heating jig in a state in which the base body 10 is placed at down side, and when the stacked body reaches a predetermined temperature, the weight is applied from the lid body 30 side with a weighting jig for a predetermined time. On this occasion, the weighting jig is also heated. In general, the term “eutectic substance” means an alloy formed by solidifying a mixture in a liquid phase state of two or more kinds of metals.

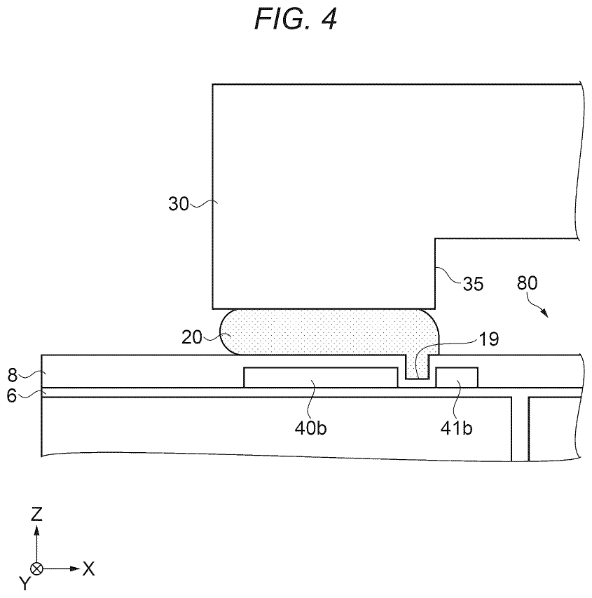

FIG. 4 is an enlarged view of the part b of FIG. 2, and shows an aspect of the metal eutectic layer 20 after bonding.

When the first bonding part 15 and the second bonding part 16 are bonded to each other, the bonding material is softened and melted by the application of the heat and the weight, and a part of the bonding material is crushed and forms a protrusion.

FIG. 4 shows this state, and it is understood that an end portion at the sensor element 80 side of the metal eutectic layer 20 protrudes, but is fitted into a recessed part 19 due to the second dummy pattern 41b which functions as a bank. The recessed part 19 is a groove-shaped recess formed in the insulating layer 8 as an upper layer between the first dummy pattern 40b and the second dummy pattern 41b. The recessed part 19 is formed in a quadrangular annular shape between the first dummy pattern 40 and the second dummy pattern 41 in a plan view.

In this way, the second dummy pattern 41b functions as a bank preventing the protrusion of the metal eutectic layer 20, and prevents the metal eutectic layer 20 from entering the sensor element 80 side.

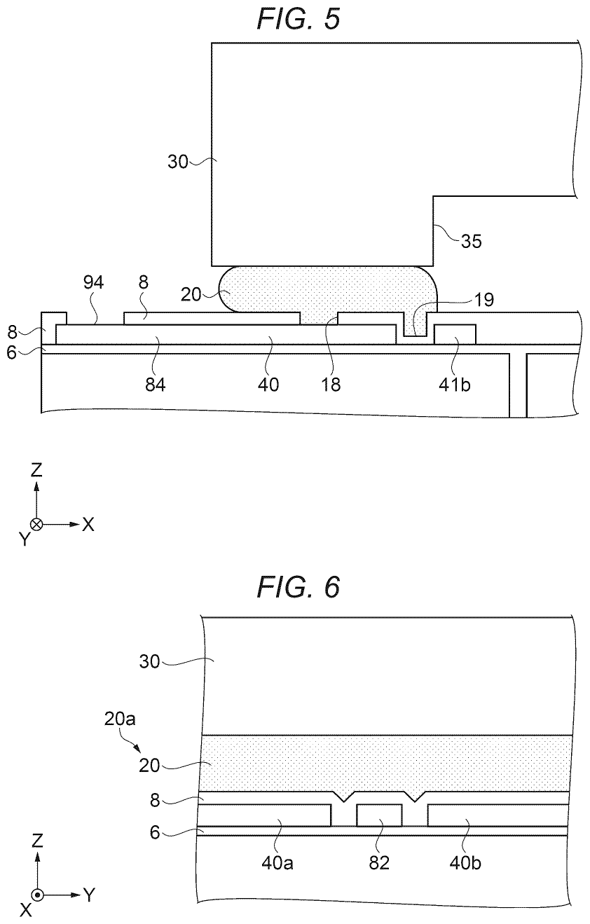

FIG. 5 is a cross-sectional view along the line c-c in FIG. 1.

FIG. 5 is a cross-sectional view of the terminal 94 as the GND terminal and the interconnection 84, and corresponds to FIG. 4.

As shown in FIG. 1, the terminal 94 is coupled to the first dummy pattern 40 with the interconnection 84. Further, as shown in FIG. 5, a contact part 18 is disposed in a part of the insulating layer 8 on the first dummy pattern 40. The contact part 18 is a contact hole, and the first dummy pattern 40 and the metal eutectic layer 20 are electrically coupled to each other by filling the contact part 18 as an opening part with a part of the metal eutectic layer 20 when performing bonding. In other words, the GND potential is applied to the first dummy pattern 40 as the first potential, the first dummy pattern 40 is electrically coupled to the metal eutectic layer 20, and the first potential is applied to the lid body 30 via the metal eutectic layer 20.

FIG. 6 is a cross-sectional view along the line d-d in FIG. 1.

FIG. 6 is a cross-sectional view in extending direction of the Y direction of the bonding region 20a, and the interconnection 82 is observed between the first dummy pattern 40a and the first dummy pattern 40b.

Here, insulating layer 8 on the the interconnection 82 is slightly recessed with the first dummy pattern 40a and with the first dummy pattern 40b, but since the distance between the interconnection 82 and the first dummy patterns 40a, 40b is narrow, and the three parties are the same in thickness, the insulating layer is substantially flat as a whole, and is in a state in which the metal eutectic layer 20 is formed without any trouble. In other words, the first dummy pattern 40 as the dummy pattern is disposed in the bonding region 20a so as to overlap the metal eutectic layer 20 at the same height as the interconnections 81 to 84.

### Configuration of Metal Eutectic Layer

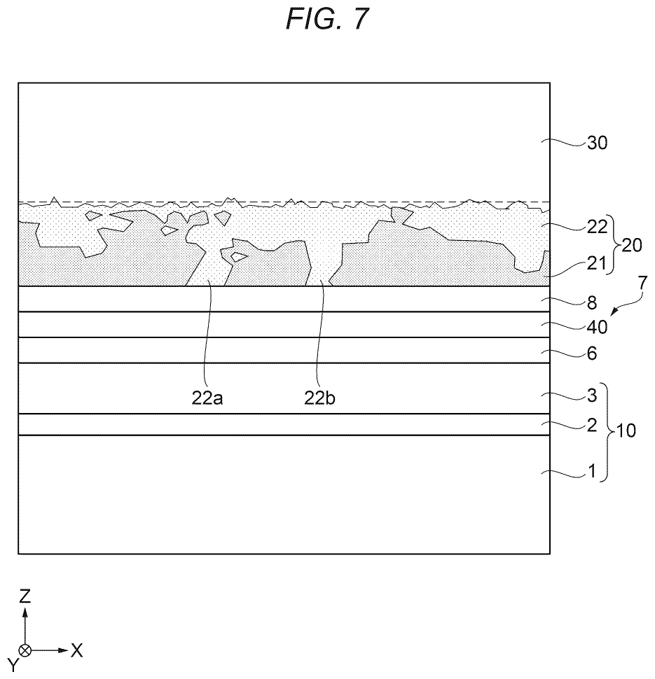

FIG. 7 is a cross-sectional view illustrating the cross-section of FIG. 4 in terms of a layer configuration.

As shown in FIG. 7, the insulating layer 6, an interconnection layer 7 including the first dummy pattern 40, the insulating layer 8, the metal eutectic layer 20, and the lid body 30 are stacked in this order on the base body 10.

The insulating layer 6 is an interlayer insulating layer, and an SiO₂ layer in a preferred example. Note that the insulating layer 6 may be an SiN layer.

The interconnection layer 7 is formed of a plurality of layers, and has, for example, a four-layer structure in which Ti, TiN, AlCu, and TiN are stacked in this order from the bottom, or a two-layer structure in which TiN and AlCu are stacked in this order. Note that the first dummy pattern 40, the second dummy pattern 41, and the interconnections 81 to 84 are also provided to the interconnection layer 7, and are formed in the same step.

The insulating layer 8 is an insulating layer, and is an SiO₂ layer in a preferred example. Note that the insulating layer 8 may be an SiN layer. In other words, the insulating layer 8 is disposed on the plurality of interconnections 81 to 84, the first dummy pattern 40, and the second dummy pattern 41 in the bonding region 20a.

An image of the metal eutectic layer 20 shown in FIG. 7 is obtained by faithfully tracing a microscope photograph of the eutectic layer.

As a result of elemental analysis, as shown in FIG. 7, the metal eutectic layer 20 is formed in a state where a first region 21 having the first metal of AlCu as a main component and a second region 22 having the second metal of Ge as a main component are adjacent to each other. The content of the first metal in the first region 21 is higher than the content of the first metal in the second region 22. The content of the second metal in the second region 22 is higher than the content of the second metal in the first region 21.

The second region 22 extends widely along the lid body 30, but a part of the second region 22 reaches a boundary with the base body 10. For example, in FIG. 6, extending portions 22a, 22b reach the base body 10. The boundary between the first region 21 and the second region 22 is indented and very complicated. Further, a portion where the second region 22 extends is larger in the second region 22 than in the first region 21.

The distribution of Ge in the metal eutectic layer 20 is not uniform but is relatively high in the second region 22, and is homogenous in that region without a concentration gradient. However, even in the first region 21, Ge is uniformly present although small in amount. The first region 21 and the second region 22 are in contact with each other without a gap wherein the contact area is larger than the plane area of the bonding region 20a. That is, the first region 21 and the second region 22 are randomly fitted, and the bonding strength thereof is made extremely high. In other words, the contact area between the first region 21 and the second region 22 is larger than the area of the bonding region 20a in which the base body 10 and the lid body 30 are bonded to each other with the metal eutectic layer 20.

In general, it is known that Ge has a diamond structure and Al has a face-centered cubic lattice structure, and when Ge is large in quantity as the main component of the eutectic layer, a solid solution having the diamond structure is formed, and when Al is large in quantity, a solid solution having the face-centered cubic lattice structure is formed. The solid solution means a material in which two elements are dissolved together to form a solid phase at a relatively uniform concentration as a whole. However, each solid solution has a different component ratio in a range of the solid solubility limit.

That is, the solid solution having the diamond structure is realized in the second region 22 rich in Ge, and the solid solution having the face-centered cubic lattice structure is realized in the first region 21 rich in Al. What gives an indication when cutting a crystal to carve out the surface is the surface energy, and it is known that when comparing Ge and Al with each other with respect to the surface energy per unit area, Ge is higher in any plane directions. In other words, in the metal eutectic layer 20, a plurality of first regions 21 having the first metal as a main component and having the face-centered cubic lattice structure, and a plurality of second regions 22 having the second metal as a main component and having the diamond structure are present, and are adjacent to each other.

As shown in FIG. 7, a part of the second region 22 reaches the boundary with the base body 10. Further, the second region 22 extends from the lid body 30 to the base body 10. In other words, the second region 22 reaches the boundary with the base body 10. That is, the second region 22 reaches the base body 10 regardless of the distance from the lid body 30. At the same time, the second region 22 rich in Ge contains Al within a range not exceeding the solid solubility limit to Ge. Further, the component ratio of Ge and Al in the second region 22 is relatively uniform and does not depend on the distance from the lid body 30. From the viewpoint of the surface energy, the bonding strength is higher when the second region 22 rich in Ge reaches the boundary with the base body 10. More preferably, the portion where the second region 22 rich in Ge extends from the lid body 30 to the base body 10 is larger in amount.

Meanwhile, on the boundary between the lid body 30 and the metal eutectic layer 20 in FIG. 7, since the second bonding part 16 made of Ge is directly deposited on the lid body 30 (FIG. 3), Ge is dispersed inside the silicon as the lid body 30. That is, the second region 22 mainly composed of Ge has a fine uneven shape in a boundary portion (the dotted line in FIG. 7) with the lid body 30 to increase the contact area to make the bonding strength high.

Further, in the above description, the sensor element 80 is assumed to be an acceleration sensor in the Z direction, but this is not a limitation, and the sensor element 80 is sufficiently an electronic component which requires an airtight environment, and may be an MEMS device such as an angular velocity sensor, or a timing device such as a crystal vibrator or a ceramic oscillator.

As described hereinabove, according to the inertial sensor 100 related to the present embodiment, the following advantages can be obtained.

The inertial sensor 100 is a capacitance change type inertial sensor, and includes the base body 10, the lid body 30, the sensor element 80 as a functional element disposed between the base body 10 and the lid body 30, the metal eutectic layer 20 for bonding the base body 10 and the lid body 30 to each other on the periphery of the sensor element 80, the plurality of interconnections 81 to 83 which pass through the bonding region 20a to be coupled to the sensor element 80, and the first dummy pattern 40 disposed so as to overlap the metal eutectic layer 20 at the same height as the interconnections 81 to 83 in the bonding region 20a.

According to this, the metal eutectic layer 20 is formed on the first dummy pattern 40 and the interconnections 81 to 83. Since the first dummy pattern 40 is the same in height as the interconnections 81 to 83, the unevenness caused by the plurality of interconnections is relaxed, the height of the bonding region 20a is substantially constant, and it becomes easy to form the metal eutectic layer 20. Further, since the base body 10 and the lid body 30 are bonded to each other with the metal eutectic layer 20 in which the first regions 21 having the face-centered cubic lattice structure and the second regions 22 having the diamond structure are randomly fitted, a high bonding strength can be obtained.

Accordingly, it is possible to provide the inertial sensor 100 which is high in bonding strength between the base body 10 and the lid body 30 and is excellent in long-term reliability.

Further, the first dummy pattern 40 is insulated from the plurality of interconnections 81 to 83, and the first dummy pattern 40 is disposed between the plurality of interconnections 81 to 83 in a plan view.

According to this, the height of the bonding region 20a in which the metal eutectic layer 20 is formed can be made substantially uniform while ensuring the necessary electrical connection.

Further, the insulating layer 8 is disposed on the plurality of interconnections 81 to 84, the first dummy pattern 40, and the second dummy pattern 41 in the bonding region 20a.

According to this, since the insulating layer 8 covers spaces between the first dummy pattern 40, the second dummy pattern 41, and the interconnections to fill the gap portions, the unevenness is relaxed, and the height of the bonding region 20a can be made more uniform.

Further, an n-th dummy pattern different from the first dummy pattern 40 may be further disposed at either one or both of the inner circumferential side and the outer circumferential side of the first dummy pattern 40.

According to this, for example, when the second dummy pattern 41 is disposed at the inner circumferential side of the first dummy pattern 40, the second dummy pattern 41b functions as a bank for preventing the protrusion of the metal eutectic layer 20, and can prevent the metal eutectic layer 20 from entering the sensor element 80 side. Accordingly, a desired performance can be obtained without hindering the operation of the sensor element 80, and the reliability can be ensured.

Further, the GND potential is applied to the first dummy pattern 40 as the first potential. As the first dummy pattern 40 is electrically coupled to the metal eutectic layer 20, the first potential is applied to the lid body 30 via the metal eutectic layer 20.

According to this, since the lid body 30 becomes the power supply potential and is electrically stabilized, it is difficult to be affected by noise, the operation of the sensor element 80 can be stabilized, and the reliability can be ensured.

Further, in the metal eutectic layer 20, a plurality of first regions 21 having the first metal as a main component and having the face-centered cubic lattice structure, and a plurality of second regions 22 having the second metal as a main component and having the diamond structure are present, and are adjacent to each other.

According to this, since the base body 10 and the lid body 30 are bonded to each other with the metal eutectic layer 20 in which the first regions 21 having the face-centered cubic lattice structure and the second regions 22 having the diamond structure are randomly fitted, a high bonding strength can be obtained. Further, the AlGe eutectic layer is formed in the entire area of the bonding region 20a, which is excellent in reliability.

Accordingly, it is possible to provide the inertial sensor 100 which is high in bonding strength between the base body 10 and the lid body 30 and is excellent in reliability.

Further, the second regions 22 reach the boundary with the base body 10.

According to this, since the second regions 22 rich in Ge reach the boundary with the base body 10, the bonding strength in the bonding region 20a increases.

Further, the second regions 22 extend from the lid body 30 to the base body 10.

According to this, the bonding strength in the bonding region 20a becomes higher.

Further, a portion where the second regions 22 extend is larger in amount in the second regions 22 than in the first regions 21. According to this, since the extending portion of the second region 22 rich in Ge is large in amount, the bonding strength in the bonding region 20a increases.

In addition, the contact area between the first region 21 and the second region 22 is larger than the area of the bonding region 20a in which the base body 10 and the lid body 30 are bonded to each other with the metal eutectic layer 20.

According to this, since the first region 21 and the second region 22 are randomly fitted with a wide contact area, the bonding strength is made extremely high.

Further, the first metal is Al, and the second metal is Ge.

According to this, the metal eutectic layer 20 high in bonding strength can be formed.

### Embodiment 2

### Different Aspect of Inertial Sensor

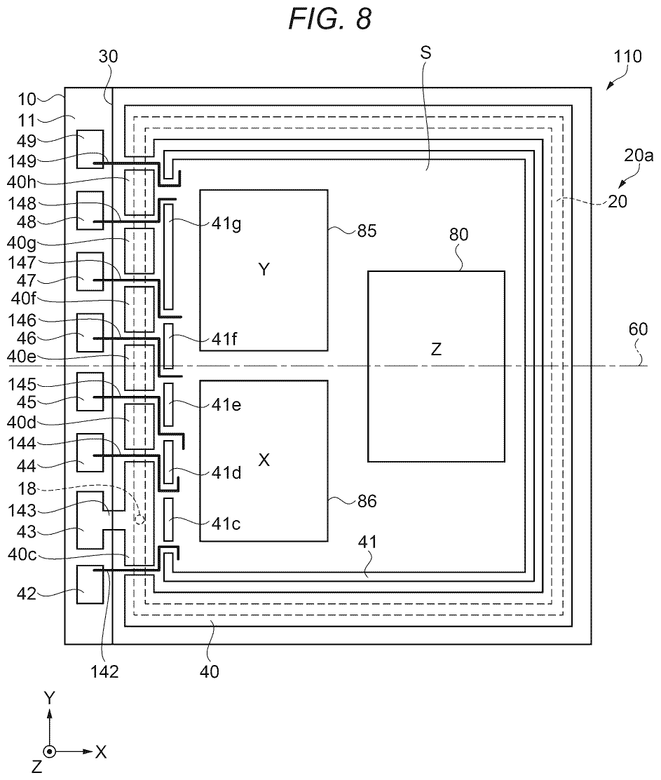

FIG. 8 is a plan view of an inertial sensor according to Embodiment 2, and corresponds to FIG. 1.

In the embodiment described above, the description is presented assuming that the inertial sensor 100 houses a single sensor element 80, but this is not a limitation, and a plurality of sensor elements may be housed. Hereinafter, regions the same as those in the embodiment described above will be denoted by the same reference numerals, and redundant descriptions thereof will be omitted.

As shown in FIG. 8, an inertial sensor 110 according to the present embodiment includes a sensor element 85 and a sensor element 86 in addition to the sensor element 80 described above.

The sensor element 85 is a capacitance change type acceleration sensor that detects the acceleration in the Y direction. The sensor element 86 is a capacitance change type sensor acceleration that detects the acceleration in the X direction. That is, the inertial sensor 110 is a triaxial acceleration sensor capable of detecting the acceleration along the three axes in the X, Y, and Z directions.

Similarly to the inertial sensor 100, the inertial sensor 110 has a configuration in which the base body 10 and the lid body 30 are bonded to each other with the metal eutectic layer 20 in the bonding region 20a, and has the housing space S inside. The three sensor elements 80, 85, and 86 are housed in the housing space S in a state in which the sensor elements 80, 85, and 86 can make a detection oscillation.

Terminals 42 to 49 for external coupling are provided to the protruding portion 11 of the base body 10.

The terminal 42 is a movable electrode terminal, and is electrically coupled to the movable electrodes of all the sensor elements 80, 85, and 86 with an interconnection 142. Note that illustration of an interconnection aspect of the interconnection 142 in the housing space S is omitted. The same applies to other interconnections 144 to 149.

The terminal 43 is a GND terminal, and is electrically coupled to the metal eutectic layer 20 with an interconnection 143 and the contact part 18.

The terminal 44 is a first fixed electrode terminal of the sensor element 86, and is electrically coupled to a first fixed electrode of the sensor element 86 with the interconnection 144.

The terminal 45 is a second fixed electrode terminal of the sensor element 86, and is electrically coupled to a second fixed electrode of the sensor element 86 with the interconnection 145.

The terminal 46 is a first fixed electrode terminal of the sensor element 85, and is electrically coupled to a first fixed electrode of the sensor element 85 with the interconnection 146.

The terminal 47 is a second fixed electrode terminal of the sensor element 85, and is electrically coupled to a second fixed electrode of the sensor element 85 with the interconnection 147.

The terminal 48 is a first fixed electrode terminal of the sensor element 80, and is electrically coupled to a first fixed electrode of the sensor element 80 with the interconnection 148.

The terminal 49 is a second fixed electrode terminal of the sensor element 80, and is electrically coupled to a second fixed electrode of the sensor element 80 with the interconnection 149.

The first dummy pattern 40 includes first dummy patterns 40c to 40h which are a plurality of island-shaped parts. Similarly, the second dummy pattern 41 includes second dummy patterns 41c to 41g as a plurality of island-shaped parts. The interconnections 144 to 149 pass between the island-shaped parts in a crank shape and then enter the housing space S.

After extending in the positive X direction, the interconnection 142 bends toward the positive Y direction, then extends along the first dummy pattern 40, and then bends toward the positive X direction to enter the housing space S. Here, the portion extending along the first dummy pattern 40 can exhibit substantially the same bank effect as that of the second dummy pattern 41.

After extending in the positive X direction, the interconnection 144 bends toward the negative Y direction, then extends along the first dummy pattern 40, and then bends toward the positive X direction to enter the housing space S.

Similarly, after extending in the positive X direction, the interconnections 145 to 147 bend toward the negative Y direction, then extend along the first dummy pattern 40, and then bend toward the positive X direction to enter the housing space S.

After extending in the positive X direction, the interconnection 148 bends toward the positive Y direction, then extends along the first dummy pattern 40, and then bends toward the positive X direction to enter the housing space S.

After extending in the positive X direction, the interconnection 149 bends toward the negative Y direction, then extends along the first dummy pattern 40, and then bends toward the positive X direction to enter the housing space S.

As described above, the interconnection 142 and the interconnections 144 to 149 each have a bending portion bending to form the crank shape, and an extending portion extending along the first dummy pattern 40, and the extending portion functions as the bank for preventing the metal eutectic layer 20 from protruding into the housing space S. In other words, the interconnection 142 and the interconnections 144 to 149 each include the bending portion and the extending portion extending along the first dummy pattern 40.

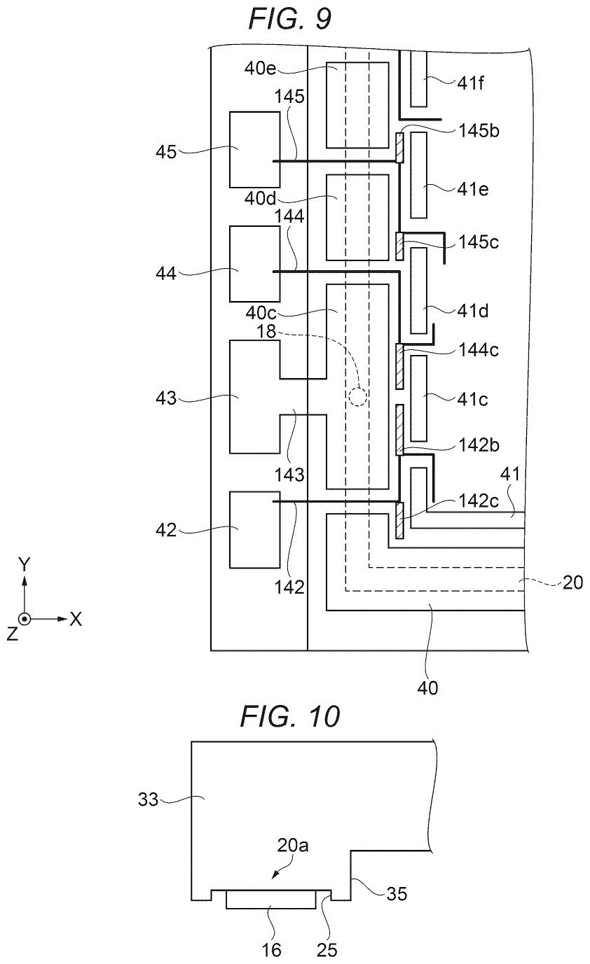

FIG. 9 is a partially enlarged view in the plan view of FIG. 8, and is an enlarged view of a peripheral portion of the terminal 43.

As shown in FIG. 9, the extending portion of the interconnection 142 is provided with an extension portion 142b branched toward the positive Y direction and an extension portion 142c branched toward the negative Y direction. Thus, the extending portion of the interconnection 142 along the first dummy pattern 40 becomes longer by the extension portions 142b and 142c added thereto. Similarly, the extending portion of the interconnection 144 is provided with an extension portion 144c that branches toward the negative Y direction. Thus, the extending portion of the interconnection 144 along the first dummy pattern 40 becomes longer by extension portion 144c added thereto.

The extending portion of the interconnection 145 is provided with an extension portion 145b branched toward the positive Y direction and an extension portion 145c branched toward the negative Y direction. Thus, the extending portion of the interconnection 145 along the first dummy pattern 40 becomes longer by the extension portions 145b and 145c added thereto. Although the interconnections 146 to 149 are not shown in FIG. 9, the extending portions are elongated in substantially the same manner as the interconnection described above.

By adding the extension portion to the extending portion of the interconnection in such a manner, a longer bank interconnection along the first dummy pattern 40 is formed, and therefore, it is possible to prevent the metal eutectic layer 20 from protruding into the housing space S.

### Embodiment 3

### Aspect Different in Lid Body

FIG. 10 is a cross-sectional view of an essential part of the lid body related to Embodiment 3, and corresponds to FIG. 3.

In the embodiments described above, the description is presented assuming that the protrusion prevention configuration for the metal eutectic layer 20 is provided to the base body 10 side, but the protrusion prevention configuration for the metal eutectic layer 20 may be provided to the lid body 30 side. Hereinafter, regions the same as those in the embodiments described above will be denoted by the same reference numerals, and redundant descriptions thereof will be omitted.

FIG. 10 is an enlarged view of the vicinity of the periphery of the bonding region 20a in the lid body 33 before bonding. In the lid body 33 in the present embodiment, a recessed part 25 is disposed along the bonding region 20a. The recessed part 25 is a groove having a flat bottom surface, and before bonding, the second bonding part 16 is formed in the recessed part 25 as shown in FIG. 10.

When the second bonding part 16 is bonded to the first bonding part 15 to form the metal eutectic layer 20, the recessed part 25 exerts the function of absorbing the protrusion of the metal eutectic layer 20 inside the recessed part 25 to prevent the outflow toward the lateral direction. In other words, the lid body 33 is provided with the recessed part 25 extending along the bonding region 20a.

The lid body 33 can be applied instead of the lid body 30 of the inertial sensors 100, 110 described above, and by using the lid body 33, the bank effect can further be enhanced.

### Embodiment 4

### Application to Inertial Measurement Device

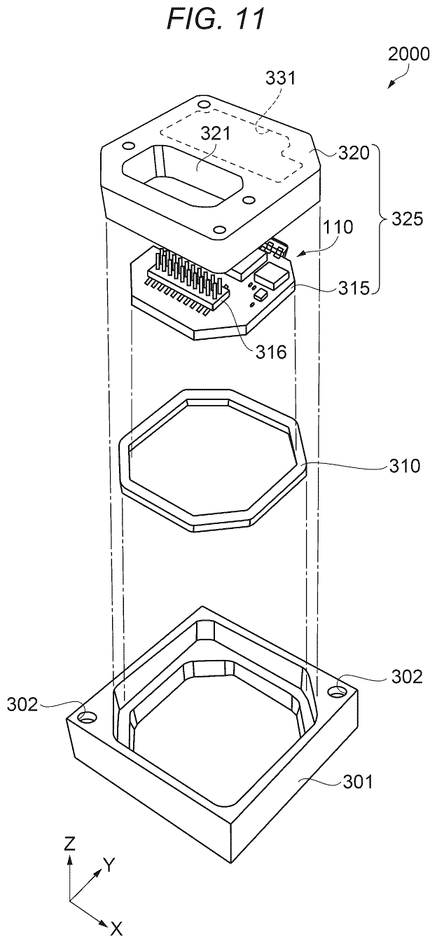

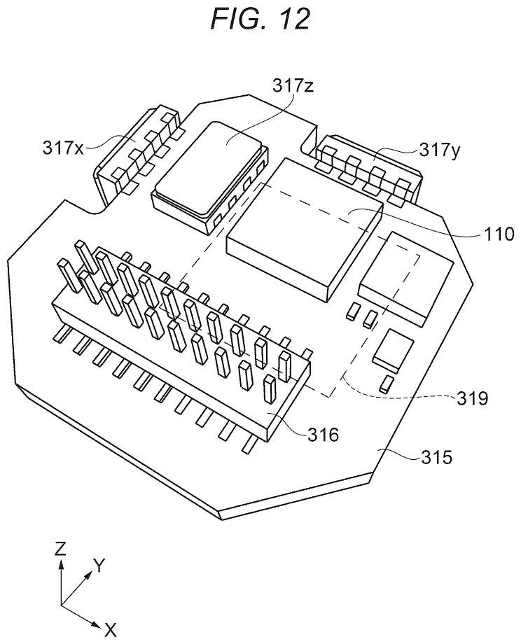

FIG. 11 is an exploded perspective view of an inertial measurement device. FIG. 12 is a perspective view of a board.

The inertial sensor 110 is installed in an inertial measurement device 2000 according to the present embodiment shown in FIG. 11. The inertial measurement device 2000 is a rectangular solid having a substantially square planer shape.

The inertial measurement device 2000 is an inertial measurement sensor unit (IMU: Inertial Measurement Unit) that detects a posture and a behavior of a mounting target body such as a car or a robot. The inertial measurement device 2000 functions as a so-called six-axis motion sensor including a triaxial acceleration sensor and angular velocity sensors around the three axes.

The inertial measurement device 2000 includes an outer case 301, a bonding member 310, and a sensor module 325 on which the inertial sensor 110 is mounted.

An outer shape of the outer case 301 is a rectangular solid having a substantially square planar shape similarly to the whole shape of the inertial measurement device 2000, and screw holes 302 are respectively formed in the vicinity of two vertexes located in the diagonal direction of the square shape. With two screws inserted into these screw holes 302 located at the two places, the inertial measurement device 2000 can be fixed to a mounting target surface of the mounting target body such as a car.

Further, the outer case 301 has a box-like shape, and the sensor module 325 is housed in the outer case 301. Specifically, there is adopted a configuration in which the sensor module 325 is inserted into the outer case 301 with the bonding member 310 interposed therebetween.

The sensor module 325 includes an inner case 320 and a board 315.

The inner case 320 is a member that supports the board 315, and the board 315 is bonded to a lower surface of the inner case 320 via an adhesive.

Further, the inner case 320 is shaped so as to be fitted inside the outer case 301. The inner case 320 is provided with a recessed part 331 for preventing contact with the board 315 and an opening 321 for exposing a connector 316 described later. The inner case 320 is bonded to the outer case 301 via the bonding member 310.

Then, the board 315 on which the inertial sensor 110 is mounted will be described.

As shown in FIG. 12, the inertial sensor 110, the connector 316, an angular velocity sensor 317z for detecting angular velocity around the Z axis, and so on are mounted on a surface at the inner case 320 side as an upper surface of the board 315. An angular velocity sensor 317x for detecting the angular velocity around the X axis and an angular velocity sensor 317y for detecting the angular velocity around the Y axis are mounted on side surfaces of the board 315. The inertial sensor 100 may be mounted instead of the inertial sensor 110.

Further, a control 319 serving as a IC controller is mounted on a surface at the outer case 301 side as a lower surface of the board 315. The control IC 319 is a micro controller unit (MCU), incorporates a storage including a nonvolatile memory, an A/D converter, and so on, and controls each unit of the inertial measurement device 2000. The storage stores a program in which an order and contents for detecting the acceleration and the angular velocity are defined, a program which digitalizes detection data to be incorporated into packet data, accompanying data, and so on. Note that a plurality other electronic components is mounted on the board 315 besides the above.

According to such an inertial measurement device 2000, since the inertial sensor 110 is used, it is possible to provide the inertial measurement device 2000 which enjoys the advantages related to the embodiments described above and is excellent in reliability.

What is claimed is:

1. An inertial sensor of a capacitance change type, comprising:
a base body;
a lid body;
a functional element disposed between the base body and the lid body;
a metal eutectic layer configured to bond the base body and the lid body to each other in a bonding region located on a periphery of the functional element;
a plurality of interconnections which passes through the bonding region to be coupled to the functional element; and
a dummy pattern disposed in the bonding region so as to overlap the metal eutectic layer at a same height as the interconnections.

2. The inertial sensor according to claim 1, wherein
the dummy pattern is insulated from the plurality of interconnections, and
the dummy pattern is disposed between the plurality of interconnections in a plan view.

3. The inertial sensor according to claim 2, wherein
an insulating layer is disposed on the plurality of interconnections and the dummy pattern in the bonding region.

4. The inertial sensor according to claim 3, further comprising:
an n-th dummy pattern which is different from a first dummy pattern identical to the dummy pattern, and located at either one or both of an inner circumferential side and an outer circumferential side of the first dummy pattern.

5. The inertial sensor according to claim 3, wherein
a first potential is applied to the dummy pattern,
the dummy pattern is electrically coupled to the metal eutectic layer, and
the first potential is applied to the lid body via the metal eutectic layer.

6. The inertial sensor according to claim 3, wherein
the interconnection includes a bending portion and an extending portion extending along the dummy pattern.

7. The inertial sensor according to claim 5, wherein
the lid body is provided with a recessed part extending along the bonding region.

8. The inertial sensor according to claim 4, wherein
in the metal eutectic layer, a plurality of first regions having a first metal as a main component and having a face-centered cubic lattice structure, and a second region having a second metal as a main component and having a diamond structure are present, and are adjacent to each other.

9. The inertial sensor according to claim 8, wherein
the second region reaches a boundary with the base body.

10. The inertial sensor according to claim 9, wherein
the second region extends from the lid body to the base body.

11. The inertial sensor according to claim 10, wherein
a portion where the second region extends is larger in amount in the second region than in the first region.

12. The inertial sensor according to claim 11, wherein
a contact area between the first region and the second region is larger than an area of the bonding region where the base body and the lid body are bonded to each other with the metal eutectic layer.

13. The inertial sensor according to claim 12, wherein
the first metal is Al, and the second metal is Ge.

14. An electronic component comprising:
a base body;
a lid body;
a functional element disposed between the base body and the lid body;
a metal eutectic layer configured to bond the base body and the lid body to each other in a bonding region located on a periphery of the functional element;
a plurality of interconnections which passes through the bonding region to be coupled to the functional element; and
a dummy pattern disposed in the bonding region so as to overlap the metal eutectic layer at a same height as the interconnections.

15. The electronic component according to claim 14, wherein
the dummy pattern is insulated from the plurality of interconnections, and
the dummy pattern is disposed between the plurality of interconnections in a plan view.

16. The electronic component according to claim 15, wherein
an insulating layer is disposed on the plurality of interconnections and the dummy pattern in the bonding region.

17. The electronic component according to claim 16, further comprising:
an n-th dummy pattern which is different from a first dummy pattern identical to the dummy pattern, and located at either one or both of an inner circumferential side and an outer circumferential side of the first dummy pattern.

18. The electronic component according to claim 16, wherein
a first potential is applied to the dummy pattern,
the dummy pattern is electrically coupled to the metal eutectic layer, and
the first potential is applied to the lid body via the metal eutectic layer.

19. The electronic component according to claim 17, wherein
in the metal eutectic layer, a plurality of first regions having a first metal as a main component and having a face-centered cubic lattice structure, and a second region having a second metal as a main component and having a diamond structure are present, and are adjacent to each other.

20. The electronic component according to claim 19, wherein
the second region reaches a boundary with the base body.
